(19) United States
(12) Patent Application Publication
(10) Pub. No.: US 2007/0178666 A1
(43) Pub. Date: Aug. 2, 2007

(54) INTEGRATED CIRCUIT SYSTEM WITH WAFERSCALE SPACER SYSTEM

(75) Inventors: Byung Tai Do, Singapore (SG); Sung Uk Yang, Singapore (SG)

Correspondence Address: ISHIMARU & ZAHRT LLP, 333 W. EL CAMINO REAL, SUITE 330, SUNNYVALE, CA, 94087, US

(73) Assignee: STATS CHIPPAC LTD., Singapore (SG)

(21) Appl. No.: 11/307,317

(22) Filed: Jan. 31, 2006

(51) Int. Cl. H01L 21/00

(52) U.S. Cl. 438/460; 438/464

(57) ABSTRACT

An integrated circuit system is provided including forming integrated circuits on a wafer using a semiconductor manufacturing process; forming a waferscale spacer system on the integrated circuits on the wafer using the semiconductor manufacturing process; and singulating the wafer to have portions of the waferscale spacer system on the integrated circuits after singulation.

### TECHNICAL FIELD

The present invention relates generally to integrated circuit manufacturing and more particularly to stacked packages using a waferscale spacer and a method for manufacturing such a waferscale spacer.

### BACKGROUND ART

Consumer electronics requirements demand more integrated circuits in an integrated circuit package while paradoxically providing less physical space in the system for the increased integrated circuits content. Continuous cost reduction is another requirement. Some technologies primarily focus on integrating more functions into each integrated circuit. Other technologies focus on stacking these integrated circuits into a single package. While these approaches provide more functions within an integrated circuit, they do not fully address the requirements for lower height, smaller space, and cost reduction.

One proven way to reduce cost is to use mature package technologies with existing manufacturing methods and equipments, or in some cases eliminate some of the existing steps and equipments. Paradoxically, the reuse of existing manufacturing processes does not typically result in the reduction of package dimensions. Still the demand continues for lower cost, smaller size and more functionality.

Stacking more integrated circuits into a package is one way to squeeze more integrated circuit content into smaller real estate. Thinning the wafers and integrated circuits provide lower height integrated circuit stacks and packages. As the thinning process evolves to more aggressive “thinness” of the wafers and the integrated circuits, the thinned integrated circuits are more prone to damage throughout the silicon manufacturing and packaging processes.

Existing stacked packages, in case of same size integrated circuit die application, requires separate spacer attachment between upper and lower integrated circuit die to lift up the upper integrated circuit die for enabling wire bonding and preventing wires from touching the edge of the lower integrated circuit die. Typically, a spacer is silicon die or film and prepared by additional semiconductor assembly processes. The silicon spacer manufacturing and packaging processes requires the spacer wafer thinning, the spacer wafer mount and sawing, and the spacer attach and cure. The film spacer calls for the cut and place process.

The silicon spacer handling throughout the manufacture and package assembly processes constrains the spacer patterns and size. Similarly, film or paste spacers also constrain the spacer patterns and size. Both processes do not keep pace with the shrinking geometries of integrated circuits without changes/capital investments to the manufacture processes and equipments, do not optimally support the continued reduction of the integrated circuit thickness, and do not optimally provide lower package height.

Thus, a need still remains for a integrated circuit system providing low cost manufacturing as well as reduce the integrated circuit package height. In view of the ever-increasing need to save costs and improve efficiencies, it is more and more critical that answers be found to these problems.

Solutions to these problems have been long sought but prior developments have not taught or suggested any solutions and, thus, solutions to these problems have long eluded those skilled in the art.

### DISCLOSURE OF THE INVENTION

The present invention provides an integrated circuit system including forming integrated circuits on a wafer using a semiconductor manufacturing process, forming a waferscale spacer system on the integrated circuits on the wafer using the semiconductor manufacturing process, and singulating the wafer to have portions of the waferscale spacer system on the integrated circuits after singulation.

Certain embodiments of the invention have other aspects in addition to or in place of those mentioned or obvious from the above. The aspects will become apparent to those skilled in the art from a reading of the following detailed description when taken with reference to the accompanying drawings.

### BRIEF DESCRIPTION OF THE DRAWINGS

FIG. 1 is a cross-sectional view of a first integrated circuit system with a first waferscale spacer system in an embodiment of the present invention;

FIG. 2 is a cross-sectional view of a second integrated circuit system with a second waferscale spacer system in an alternative embodiment of the present invention;

FIG. 3 is a plan view of the structure of FIG. 2;

FIG. 4 is a top view of integrated circuit die with third waferscale spacer systems after singulation from a wafer;

FIG. 5 is a cross-sectional view of the structures of FIG. 4 in an embodiment in accordance with the present invention;

FIG. 6 is another cross-sectional view of the structures of FIG. 4 in another embodiment in accordance with the present invention;

FIG. 7 is a top view of the integrated circuit die with a fourth waferscale spacer system in an alternative embodiment of the present invention;

FIG. 8 is a cross-sectional view of the structures of FIG. 7;

FIG. 9 is a top view of the integrated circuit dies with fifth waferscale spacer systems in an alternative embodiment of the present invention;

FIG. 10 is a cross-sectional view of the structures of FIG. 9;

FIG. 11 is a top view of the integrated circuit dies with different waferscale spacer systems in further alternative embodiments of the present invention;

FIG. 12 is a cross-sectional view of the sixth integrated circuit system on the wafer of FIG. 11; and

FIG. 13 is a flow chart of an integrated circuit system for manufacturing the integrated circuit system in an embodiment of the present invention.

### BEST MODE FOR CARRYING OUT THE INVENTION

In the following description, numerous specific details are given to provide a thorough understanding of the invention. However, it will be apparent that the invention may be practiced without these specific details. In order to avoid obscuring the present invention, some well-known system configurations, and process steps are not disclosed in detail. Likewise, the drawings showing embodiments of the apparatus are semi-diagrammatic and not to scale and, particularly, some of the dimensions are for the clarity of presentation and are shown greatly exaggerated in the figures. In addition, where multiple embodiments are disclosed and described having some features in common, for clarity and ease of illustration, description, and comprehension thereof, similar and like features one to another will ordinarily be described with like reference numerals.

The term “horizontal” as used herein is defined as a plane parallel to the conventional integrated circuit surface, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” indicates direct contact between elements.

The term “processing” as used herein includes deposition of material, patterning, exposure, development, etching, cleaning, molding, and/or removal of the material or as required in forming a described structure at a semiconductor device size level.

The term “waferscale” as used herein includes structures the size of a silicon wafer in which and upon which integrated circuits and micro electronic machines are formed. Waferscale structures are characterized by having sharp, about 90°, corners for submicron-sized structures.

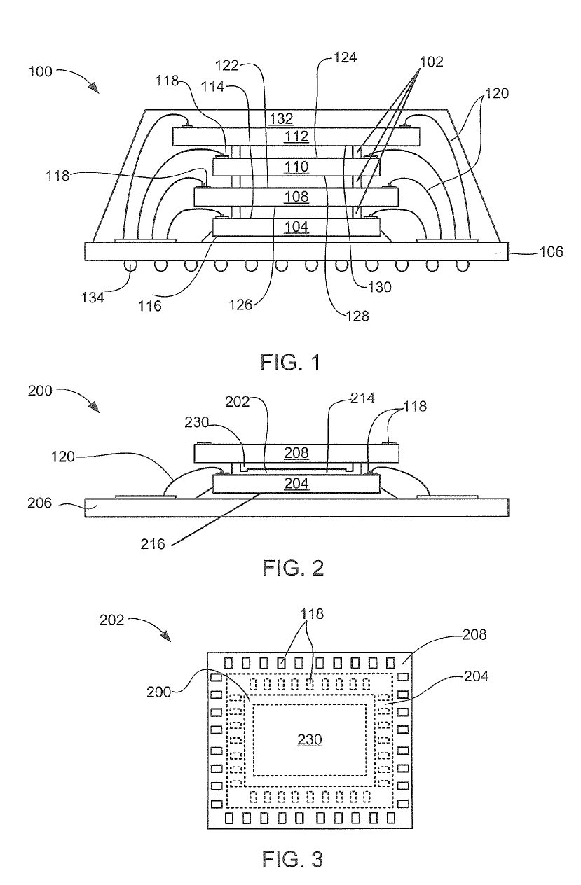

Referring now to FIG. 1, therein is shown a cross-sectional view of a first integrated circuit system 100 with a first waferscale spacer system 102 in an embodiment of the present invention. The integrated circuit system 100 includes a first integrated circuit 104 on a substrate 106 and a second integrated circuit 108 stacked above the first integrated circuit 104. The integrated circuit system 100 also includes a third integrated circuit 110 above the second integrated circuit 108 and below a fourth integrated circuit 112.

The first integrated circuit 104 has a first active side 114 and a first non-active side 116. The first active side 114 has circuitry (not shown), bonding pads 118, and the first integrated circuit system 100 fabricated thereon. The first wafer scale system 102 may be manufactured in a number of semiconductor processes, such as spin coat and patterning (photolithography and etching process), screen printing and patterning (photolithography and etching process), selective screen pattern printing, dispensing, pre-formed pattern attach, or molding. The first waferscale spacer system 102 may be made from a number of materials, such as an organic material, inorganic material, or metallic material.

The first waferscale spacer system 102 is manufactured at the boundary of the first integrated circuit 104 but not extending beyond the bonding pads 118. The height of the first waferscale spacer system 102 is predetermined providing clearance between the first integrated circuit 104 and the second integrated circuit 108 for electrical interconnects 120, such as bond wires, as well as for the attachment process of the electrical interconnects 120, such as wire bonding or reserve stitch stand-off bump (RSSB).

It has been discovered that the integrated circuit system with waferscale spacer provides control previously unachieved of the spacer pattern features on the wafer and the height of the spacers on or in an integrated circuit, especially for thinned wafers. Spacer patterns may vary depending on the design requirements. Spacer patterns may be designed to spread the stacking force, without tilting of the integrated circuits or damage to the integrated circuits, on very thin wafers and integrated circuits. Spacer patterns and materials may be designed to provide insulation, thermal conductivity, or shielding, as required. The integrated circuit system may control the height to take advantage of low height electrical interconnect technologies and provide the lowest possible stack profile.

It has also been discovered that the integrated circuit system with waferscale spacers may also provide structures not used for stacking integrated circuits, such as in micro-electro-mechanical (MEM) structures, or creating structures for optics. The integrated circuit system may be formed using various methods, such as negative resist, positive resist, deep reactive etch, anisotropic wet etch, isotropic wet etch, thin-film deposition, or electroplating, and materials, as required.

Similarly, the first waferscale spacer system 102 is manufactured on a second active side 122 and a third active side 124 of the second integrated circuit 108 and the third integrated circuit 110, respectively. The first waferscale spacer system 102 is located at the boundary of the second active side 122 and the third active side 124 within the locations of the bonding pads 118 of the second integrated circuit 108 and the third integrated circuit 110, respectively.

The second integrated circuit 108 stacks above the first integrated circuit 104 with an adhesive (not shown) attaching a second non-active side 126 of the second integrated circuit 108 to the top surface of the first waferscale spacer system 102 of the first integrated circuit 104. A third non-active side 128 of the third integrated circuit 110 attaches to the top surface of the first waferscale spacer system 102 of the second integrated circuit 108. A fourth non-active side 130 of the fourth integrated circuit 112 attaches to the top surface of the first waferscale spacer system 102 of the third integrated circuit 110.

An encapsulant 132 covers the first integrated circuit 104, the second integrated circuit 108, the third integrated circuit 110, the fourth integrated circuit 112, and the electrical interconnects 120. The encapsulant 132 also fills the space between the stack of the first integrated circuit 104, the second integrated circuit 108, the third integrated circuit 110, the fourth integrated circuit 112, and the first waferscale spacer system 102 of each. External interconnects 134, such as solder balls, attach to the bottom of the substrate 106. The external interconnects 134 attach to the next system level (not shown), such as a printed circuit board.

For illustrative purposes, the first integrated circuit 104, the second integrated circuit 108, and the third integrated circuit 110 are shown to have the first waferscale spacer system 102, although it is understood that the first integrated circuit 104, the second integrated circuit 108, and the third integrated circuit 110 may not have or have differently than the first waferscale spacer system 102.

Also for illustrative purposes, the first waferscale spacer system 102 is shown fabricated on the first active side 114, the second active side 122, and the third active side 124, although it is understood that the first waferscale spacer system 102 and other waferscale spacer systems (not shown) may be formed on the second non-active side 126, the third non-active side 128, the fourth non-active side 130, or on both sides.

It will be understood from the present disclosure that the waferscale spacer systems include various spacers (depicted as having the same number as the systems) with various geometric configurations. As will be subsequently disclosed, the spacers are of geometric configurations that include a dot, block, geometric shape, straight line, angled line, or a combination thereof. In other geometric configurations, there may be one or more spacers within another spacer.

Referring now to FIG. 2, therein is shown a cross-sectional view of a second integrated circuit system 200 with a second waferscale spacer system 202 in an alternative embodiment of the present invention. The second integrated circuit system 200 is shown without an encapsulation and external interconnects. The second integrated circuit system 200 includes a substrate 206 with a first integrated circuit 204 thereon and a second integrated circuit 208 above the first integrated circuit 204. The second integrated circuit system 200 is between the first integrated circuit 204 and the second integrated circuit 208.

The first integrated circuit 204 has a first active side 214 and a first non-active side 216. The first active side 214 has circuitry (not shown) and the bonding pads 118. The second waferscale spacer system 202 may be manufactured in a number of processes, such as spin coat and patterning (photolithography and etching process), screen printing and patterning (photolithography and etching process), selective screen pattern printing, dispensing, pre-formed pattern attach, or molding. The second waferscale spacer system 202 may be made from a number of materials, such as an organic material, inorganic material, or metallic material.

The second waferscale spacer system 202 is also fabricated on the first active side 214. The second integrated circuit 208 attaches to the top surface of the second waferscale spacer system 202 with an adhesive 230. The second waferscale spacer system 202 is manufactured at the boundary of the first integrated circuit 204 not extending beyond the bonding pads 118. The height of the second waferscale spacer system 202 is predetermined providing clearance between the first integrated circuit 204 and the second integrated circuit 208 for the electrical interconnects 120, such as bond wires, as well as for the attachment process of the electrical interconnects 120, such as wire bonding or reserve stitch stand-off bump (RSSB).

Referring now to FIG. 3, therein is shown a plan view of the structure of FIG. 2. The plan view depicts the first integrated circuit 204 and the second integrated circuit 208 with the bonding pads 118 at the boundaries of the first integrated circuit 204 and the second integrated circuit 208. The plan view also depicts the second waferscale spacer system 202 with the adhesive 230. The second waferscale spacer system 202 may control the bleeding of the adhesive 230 to the boundary of the top surface of the second waferscale spacer system 202 such that the adhesive 230 will not interfere with the attachment of the electrical interconnects 120 of FIG. 2.

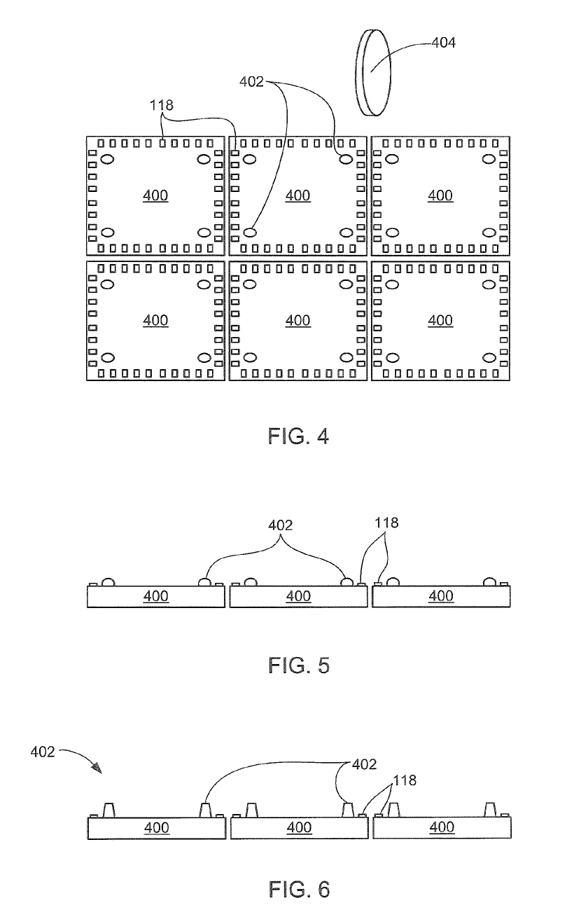

Referring now to FIG. 4, therein is shown a top view of integrated circuit die 400 with third waferscale spacer systems 402 after singulation from a wafer. The top view depicts six of the integrated circuit die 400 from the same wafer, wherein the wafer is singulated by a saw 404. The integrated circuit die 400 includes the bonding pads 118 at the boundary and the third waferscale spacer system 402. The third waferscale spacer system 402 includes spacer dots at the corners of the integrated circuit die 400 and located within the locations of the bonding pads 118.

The configuration of the third waferscale spacer system 402 provides X-Y axes support during stacking of the integrated circuit die 400 or other integrated circuits. The support provides resistance to tilt of the integrated circuit die 400 during stacking adhesion and curing. The dots of the third waferscale spacer system 402 may be used for small die sizes as well as large die sizes.

Referring now to FIG. 5, therein is shown across-sectional view of the structures of FIG. 4. For illustrative purposes, the third waferscale spacer system spacers 402 are shown as substantially the same height on the integrated circuit die 400, but it should be understood that the height of the spacers 402 may differ among the integrated circuit die 400.

Referring now to FIG. 6, therein is shown another cross-sectional view of the structures of FIG. 4 in another embodiment in accordance with the present invention. For illustrative purposes, the third waferscale spacer system spacers 402 are shown as vertical trapezoids or frustums.

Also for illustrative purposes, the integrated circuit die 400 is shown with four dots at the corners of the integrated circuit die 400, although it is understood that the number and locations of the dots may differ.

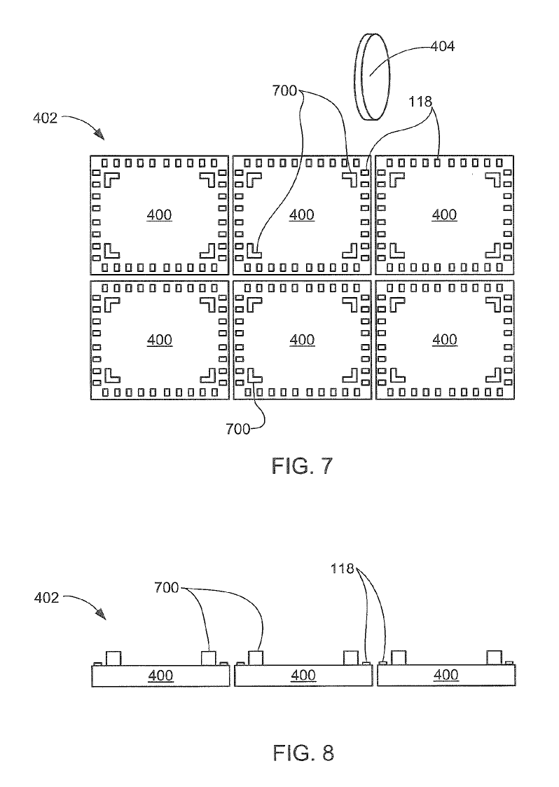

Referring now to FIG. 7, therein is shown a top view of the integrated circuit die 400 with a fourth waferscale spacer system 700 in an alternative embodiment of the present invention. The top view depicts six instances of the integrated circuit die 400 after singulated. The integrated circuit die 400 includes the bonding pads 118 at the edges.

The fourth waferscale spacer system 700 shows four instances of perpendicular segments at the corners of the integrated circuit die 400 and located within the locations of the bonding pads 118. Each segment of the perpendicular segments aligns with the nearest side of the integrated circuit die 400. The two segments of the perpendicular segments along one side of the integrated circuit die 400 are aligned to each other.

The configuration of the fourth waferscale spacer system 700 and each instance of the perpendicular segments provide additional X-Y axes support during stacking of the integrated circuit die 400 or other integrated circuits (not shown). The additional support provides more resistance to tilt of the integrated circuit die 400 during stacking adhesion and curing. The space between the perpendicular segments may be used for underfill molding compound between the integrated circuit die 400, stacked, or other integrated circuits.

Referring now to FIG. 8, therein is shown a cross-sectional view of the structures of FIG. 7. For illustrative purposes, the fourth waferscale spacer system 700 is shown as substantially the same height on one instance of the integrated circuit die 400 to the another instance of the integrated circuit die 400, although it is understood the height of the fourth waferscale spacer system 700 may differ from one of the integrated circuit die 400 to the another.

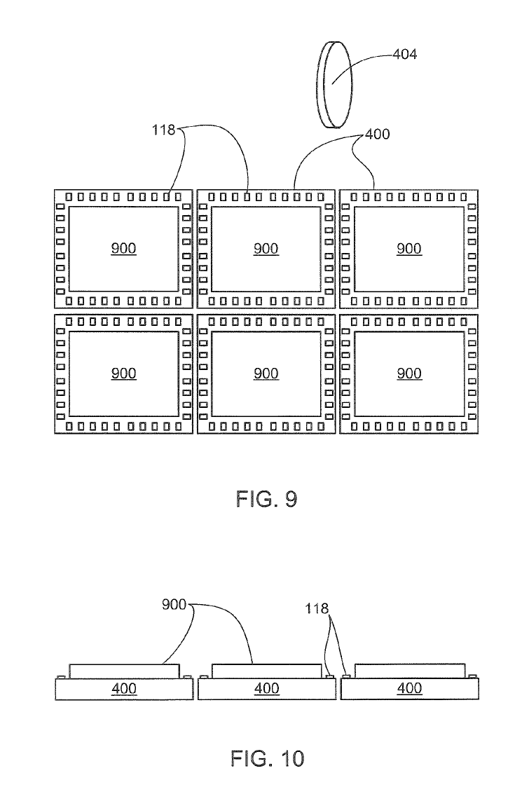

Referring now to FIG. 9, therein is shown a top view of the integrated circuit dies 400 with fifth waferscale spacer systems 900 in an alternative embodiment of the present invention. The top view depicts six instances of the integrated circuit die 400 singulated by the saw 404 from a common wafer with the spacers 900 having the same configuration. The integrated circuit die 400 includes the bonding pads 118 at the edges.

The fifth waferscale spacer systems 900 each has a single spacer 900 of a rectangular geometric configuration where the corners are towards the corners of the integrated circuit dies 400 and is located within locations of the bonding pads 118. The sides of the spacers 900 align with the nearest side of the integrated circuit die 400.

The configuration of the fifth waferscale spacer systems 900 provide substantially uniform X-Y axes surface and support during stacking of the integrated circuit die 400 or other integrated circuits (not shown). The substantially uniform support provides more resistance to tilt of the integrated circuit die 400 or cracking during stacking adhesion and curing. This uniform support may used with the integrated circuit die 400 that have undergone substantial thinning. The uniform surface may be also be used to provide maximum surface contact for maximum thermal dissipation.

Referring now to FIG. 10, therein is shown a cross-sectional view of the structures of FIG. 9. The integrated circuit dies 400 are shown as having the spacers 900 with rectangular geometric shapes. For illustrative purposes, the fifth waferscale spacer systems 900 is shown as substantially the same height on one instance of the integrated circuit die 400 as another, although it is understood the height of the fifthwaferscale spacer systems 900 may differ from one instance of the integrated circuit die 400 to the another.

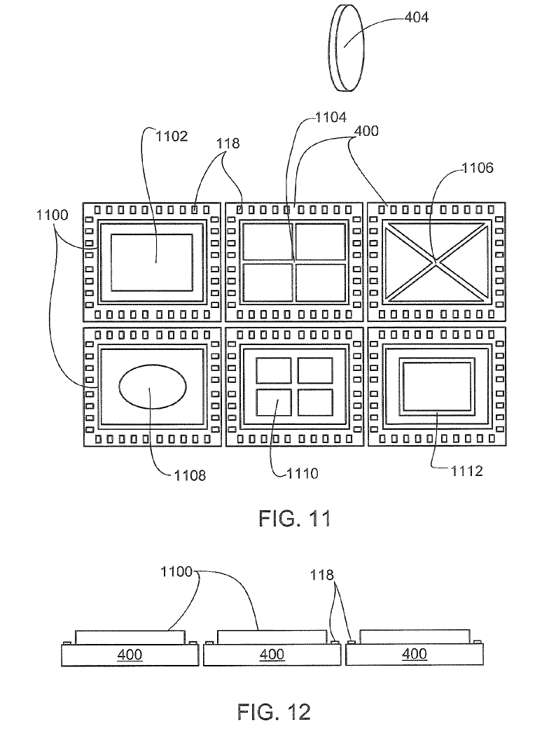

Referring now to FIG. 11, therein is shown a top view of the integrated circuit dies 400 with different waferscale spacer systems 1100 through 1112 in further alternative embodiments of the present invention. The top view depicts six instances of the integrated circuit die 400 coming from a common wafer with the spacers 1100 through 1112 having different configurations on each of the integrated circuit die 400. The common wafer can be for testing spacer configurations, for different spacer configurations within the same package, or different spacer configurations for different package. The integrated circuit die 400 includes the bonding pads 118 at the edges.

A first embodiment has a rectangular ring spacer 1100 enclosing a rectangular spacer 1102. The rectangular ring spacer 1100 is located within the bonding pads 118. The rectangular ring spacer 1100 provides maximum perimeter support and resistance to tilt of the integrated circuit die 400 or other integrated circuits (not shown) while stacking. The rectangular spacer 1102 provides uniform surface and support. This uniform support may be used with the integrated circuit die 400 that have undergone substantial thinning. The uniform surface may be also be used to provide maximum surface contact for maximum thermal dissipation or shielding. The space between the rectangular ring spacer 1100 and the rectangular spacer 1102 may provide a trench for adhesive bleeding.

A second embodiment shows a grid spacer 1104 with the equivalent of a rectangular ring spacer enclosing grid lines, all located within the bonding pads 118.

The rectangular ring spacer of the grid spacer 1104 provides maximum perimeter support and resistance to tilt of the integrated circuit die 400 or other integrated circuits while stacking. The grid lines of the grid spacer 1104 provides additional X-Y support while stacking, such as stacking thinned integrated circuits, with minimal surface contact. A sufficient number of the integrated circuit die 400 in a stacked structure (not shown) may develop a thermal gradient such that some expansion difference may occur, but the grid spacer 1104 can isolate the different integrated circuit die 400 of the stack. Quadrants of the grid structure may provide a space for adhesive bleeding.

A third embodiment shows a crossed box spacer 1106 with the equivalent of a rectangular ring spacer enclosing a X-angled lines spacer, all located within the bonding pads 118. The ends of each segment of the angled lines spacer are located at the diagonal corners of the rectangular ring spacer.

The rectangular ring spacer of the crossed box spacer 1106 provides maximum perimeter support and resistance to tilt of the integrated circuit die 400 or other integrated circuits (not shown) while stacking. The X-angled lines spacer provides additional X-Y support while stacking, such as stacking thinned integrated circuits, with minimal surface contact. A sufficient number of the integrated circuit die 400 in a stacked structure (not shown) may develop a thermal gradient such that some expansion difference may occur, but the grid spacer 1104 can isolate the different integrated circuit die 400 of the stack. Quadrants of theX-angled structure may provide a space for adhesive bleeding.

A fourth embodiment has the rectangular ring spacer 1100 enclosing a geometric spacer 1108, such as an elliptical spacer. The rectangular ring spacer 1100 is located within the bonding pads 118. The rectangular ring spacer 1100 provides maximum perimeter support and resistance to tilt of the integrated circuit die 400 or other integrated circuits (not shown) while stacking. The geometric spacer 1108 provides uniform surface and support. This uniform support may used with the integrated circuit die 400 that have undergone substantial thinning. The uniform surface may be also be used to provide maximum surface contact for maximum thermal dissipation or shielding. The space between the rectangular ring spacer 1100 and the geometric spacer 1108 may provide a space for adhesive bleeding.

A fifth embodiment has the rectangular ring spacer 1100 enclosing four rectangular spacers 1110. The rectangular ring spacer 1100 is located within the bonding pads 118. The rectangular ring spacer 1100 provides maximum perimeter support and resistance to tilt of the integrated circuit die 400 or other integrated circuits (not shown) while stacking. Each of the four rectangular spacers 1110 provides uniform surface and support with space between the rectangular spacers. This uniform support may used with the integrated circuit die 400 that have undergone substantial thinning. The uniform surface may be also be used to provide maximum surface contact for maximum thermal dissipation or shielding. The space between the rectangular ring spacer 1100 and the four rectangular spacers 1110 as well as the inter-spaces of the four rectangular spacers 1110 may provide spaces for adhesive bleeding.

A sixth embodiment has two concentric rectangular ring spacers 1100 and 1112 located within the bonding pads 118. The rectangular ring spacer 1100 provides maximum perimeter support providing resistance to tilt of the integrated circuit die 400 or other integrated circuits (not shown) while stacking. The inner rectangular ring spacer 1112 provides additional X-Y support while stacking, such as stacking thinned integrated circuits, with minimal surface contact. A sufficient number of the integrated circuit die 400 in a stacked structure (not shown) may develop a thermal gradient such that some expansion difference may occur, but the two concentric rectangular ring spacers 1100 and 1112 can isolate the different integrated circuit die 400 of the stack. The space between the two concentric rectangular ring spacers 1100 and 1112 may provide spaces for adhesive bleeding.

Referring now to FIG. 12, therein is shown a cross-sectional view of the structures of FIG. 11. The cross-sectional view depicts the three instances of the integrated circuit die 400 with the with different waferscale spacer systems 1100 through 1112 shown as rectangular geometric shape. For illustrative purposes, the with different waferscale spacer systems 1100 through 1112 are shown as substantially the same height, although it is understood the height of the with different waferscale spacer systems 1100 through 1112 may differ from one instance of the integrated circuit die 400 to the another.

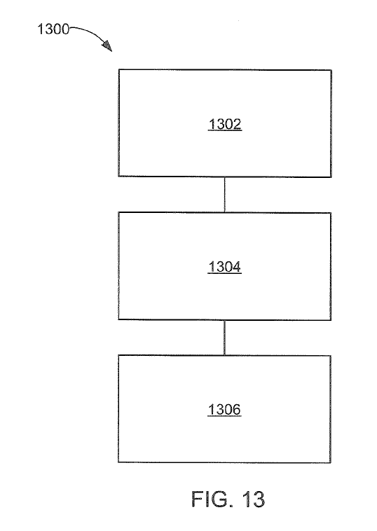

Referring now to FIG. 13, therein is shown a flow chart of an integrated circuit system 1300 for manufacturing the integrated circuit system 100 in an embodiment of the present invention. The system 1300 includes: forming integrated circuits on a wafer using a semiconductor manufacturing process in a block 1302; forming a waferscale spacer system on the integrated circuits on the wafer using the semiconductor manufacturing process in a block 1304; and singulating the wafer to have portions of the waferscale spacer system on the integrated circuits after singulation in a block 1306.

It has been discovered that the present invention has numerous aspects.

It has been discovered that the integrated circuit system with waferscale spacers provides control previously unachieved for the spacer configurations on the wafer and the height of the spacers on or in an integrated circuit, especially for thinned wafers. The waferscale spacer may vary depending on the design requirements. For example, the waferscale spacer may be designed to spread the stacking force, without tilting of the integrated circuits or damage to the integrated circuits, on very thin wafers and integrated circuits. Further, the waferscale spacer patterns and materials may be designed to provide insulation, thermal conductivity, or shielding, as required. The integrated circuit system may control the height to take advantage of low height electrical interconnect technologies and provide the lowest possible stack profile.

It has also been discovered that the integrated circuit system may also provide structures not used for stacking integrated circuits, such as in micro-electro-mechanical (MEM) structures, or creating structures for optics. The integrated circuit system may be formed using various methods, such as negative resist, positive resist, deep reactive etch, anisotropic wet etch, isotropic wet etch, thin-film deposition, or electroplating, and materials, as required.

An aspect is that the present invention is to solve the problems of the conventional spacer application for stacked packages and to provide waferscale stack package by stacking die with waferscale spacer.

Another aspect of the present invention is to eliminate conventional assembly processes for silicon, film, paste spacer preparation and application with no special machine while using conventional assembly equipments and processes.

Another aspect of the present invention is the use of the semiconductor process feature sizes used to manufacture waferscale spacer patterns and dimensions unachieved by existing methods. The semiconductor process and features may be process steps, such as resist application and etching, and feature sizes, such as line widths, heights, and other dimensions, used to fabricate circuitry on the wafer. Stacking of chips with varying die sizes requires a spacer between the die when the top die is either the same size or larger than the bottom to avoid damage to its wires. Numerous spacer materials have been used, including silicon, adhesive paste with large spacer spheres or thick tape. Silicon is widely used because it fits the infrastructure and is cost effective, but it has more processing steps. Epoxy with spacer spheres requires fewer process steps, but has more epoxy bleed. Tape or film has no bleeding, but is more costly. Each presents different advantages and shortcomings but none take advantage of feature sizes of the semiconductor processes use to manufacture the integrated circuits.

Yet another aspect of the present invention is the granularity, location, and pattern selections of the spacers possible. The integrated circuit system may be used with very small die sizes as well as very large die size, thinned or not. The integrated circuit system may also be used with bond pads for bond wires or for grid array connections. The height of the integrated circuit system may be varied with granularities previously unachieved, as required.

Thus, it has been discovered that the integrated circuit system method of the present invention furnishes important and heretofore unknown and unavailable solutions, capabilities, and functional aspects for increasing chip density in systems. The resulting processes and configurations are straightforward, cost-effective, uncomplicated, highly versatile and effective, can be implemented by adapting known technologies, and are thus readily suited for efficiently and economically manufacturing stacked integrated circuit package-in-packaged devices.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters set forth herein or shown in the accompanying drawings are to be interpreted in an illustrative and non-limiting sense.

What is claimed is:

1. An integrated circuit system comprising: forming integrated circuits on a wafer using a semiconductor manufacturing process; forming a waferscale spacer system on the integrated circuits on the wafer using the semiconductor manufacturing process; and singulating the wafer to have portions of the waferscale spacer system on the integrated circuits after singulation.

2. The system as claimed in claim 1 wherein forming the waferscale spacer system includes forming a spacer with a geometric configuration.

3. The system as claimed in claim 1 wherein forming the waferscale spacer system includes forming a spacer within another spacer.

4. The system as claimed in claim 1 wherein forming the waferscale spacer system includes forming spacers having the same configuration on different integrated circuits on the wafer.

5. The system as claimed in claim 1 wherein forming the waferscale spacer system includes forming spacers having different configurations on different integrated circuits on the wafer.

6. An integrated circuit system comprising:
forming integrated circuits on a wafer using a semiconductor manufacturing removal process;
depositing a spacer material on an active side of the integrated circuits on the wafer;
forming a waferscale spacer system on the integrated circuits on the wafer by selectively removing portions of the spacer material using the semiconductor manufacturing removal process; and
singulating the wafer to have portions of the waferscale spacer system on the integrated circuits after singulation.

7. The system as claimed in claim 6 wherein forming the waferscale spacer system includes forming a spacer with a geometric configuration comprised of a dot, block, geometric shape, straight line, angled line, or a combination thereof.

8. The system as claimed in claim 6 wherein forming the waferscale spacer system includes forming a plurality of spacers within another spacer.

9. The system as claimed in claim 6 wherein:
forming the waferscale spacer system includes forming spacers having the same configuration on different integrated circuits on the wafer; and
stacking an additional integrated circuit on at least one of the different integrated circuits.

10. The system as claimed in claim 6 wherein:
forming the waferscale spacer system includes forming spacers having different configurations on different integrated circuits on the wafer; and
stacking an additional integrated circuit on at least one of the different integrated circuits.

11. An integrated circuit system comprising:
a substrate;
an integrated circuit attached to the substrate; and
a waferscale spacer system on the integrated circuit.

12. The system as claimed in claim 11 wherein the waferscale spacer system includes a spacer with a geometric configuration.

13. The system as claimed in claim 11 wherein the waferscale spacer system includes a spacer within another spacer.

14. The system as claimed in claim 11 further comprising:
an additional integrated circuit stacked on the waferscale spacer system; and
an encapsulant encapsulating the integrated circuit, the additional integrated circuit, and the waferscale spacer system.

15. The system as claimed in claim 11 further comprising: bond wires connecting the integrated circuit to the substrate; and external interconnects on the substrate operatively connected to the bond wires.

16. The system as claimed in claim 11 further comprising:
an additional integrated circuit stacked on the waferscale spacer system, the additional integrated circuit of a different size from the integrated circuit, the additional integrated circuit having an additional waferscale spacer system thereon;
a further integrated circuit stacked on the additional waferscale spacer system, the further integrated circuit of a different size from the integrated circuit and the additional integrated circuit; and
an encapsulant encapsulating the integrated circuit, the waferscale spacer system the additional integrated circuit, the additional waferscale spacer system, and the further integrated circuit.

17. The system as claimed in claim 16 wherein the waferscale spacer system includes forming a spacer with a geometric configuration comprised of a dot, block, geometric shape, straight line, angled line, or a combination thereof.

18. The system as claimed in claim 16 wherein the waferscale spacer system includes forming a plurality of spacers within another spacer.

19. The system as claimed in claim 16 further comprising:
an additional integrated circuit stacked on the waferscale spacer system;
bond wires for connecting the integrated circuit and the additional integrated circuit to the substrate; and
an encapsulant encapsulating the integrated circuit, the additional integrated circuit, and the waferscale spacer system.

20. The system as claimed in claim 16 further comprising:
an additional integrated circuit stacked on the waferscale spacer system, the additional integrated circuit of a different size from the integrated circuit, the additional integrated circuit having an additional waferscale spacer system thereon;
a further integrated circuit stacked on the additional waferscale spacer system, the further integrated circuit of a different size from the integrated circuit and the additional integrated circuit;
bond wires for connecting the integrated circuit, the additional integrated circuit, and the further integrated circuit to the substrate; and
an encapsulant encapsulating the integrated circuit, the waferscale spacer system the additional integrated circuit, the additional waferscale spacer system, and the further integrated circuit.
